(19) United States
(12) Patent Application Publication
(10) Pub. No.: US 2024/0090196 A1
(43) Pub. Date: Mar. 14, 2024

(54) SEMICONDUCTOR STRUCTURE AND FABRICATION METHOD THEREFOR

(71) Applicant: Changxin Memory Technologies, Inc., Hefei (CN)

(72) Inventors: Liutao Zhou, Hefei (CN); Shuo Pan, Hefei (CN)

(21) Appl. No.: 18/511,875

(22) Filed: Nov. 16, 2023

Related U.S. Application Data
(63) Continuation of application No. PCT/CN2022/118313, filed on Sep. 13, 2022.

(30) Foreign Application Priority Data
Sep. 1, 2022 (CN) 202211065549.X

(51) Int. Cl. H10B 12/00

(52) U.S. Cl. CPC H10B 12/30; H10B 12/03

(57) ABSTRACT

A semiconductor structure and a fabrication method are provided. The semiconductor structure includes: a substrate, where a plurality of capacitor contact structures arranged at intervals are formed on the substrate; an isolation structure, where the isolation structure is disposed on the substrate and between adjacent capacitor contact structures, and a top surface of the isolation structure is not higher than a top surface of each capacitor contact structure; and an isolation groove, where the isolation groove extends from the top surface of the isolation structure to an interior of the isolation structure, and a spacing is provided between the isolation groove and the capacitor contact structure.

### CROSS-REFERENCE TO RELATED APPLICATIONS

This application is a continuation application of International Patent Application No. PCT/CN2022/118313, filed on Sep. 13, 2022, which claims priority to Chinese Patent Application No. 202211065549.X, filed with the China National Intellectual Property Administration on Sep. 1, 2022, and entitled “SEMICONDUCTOR STRUCTURE AND FABRICATION METHOD THEREFOR.” The above-referenced applications are incorporated herein by reference in their entirety.

### TECHNICAL FIELD

The present invention relates to the field of semiconductor manufacturing technologies, and in particular, to a semiconductor structure and a fabrication method therefor.

### BACKGROUND

Dynamic random access memory (DRAM) is a type of semiconductor storage device commonly used in computers and is composed of many repetitive storage units. Each storage unit generally includes a capacitor and a transistor. The gate of the transistor is connected to a word line, the drain of the transistor is connected to a bit line, and the source of the transistor is connected to the capacitor. The voltage signal on the word line can control the transistor to be turned on or off, thereby reading the data stored in the capacitor through the bit line or writing data into the capacitor for storage through the bit line.

The capacitor in the DRAM is electrically connected to a capacitor landing pad through its lower electrode, and forms an access path with the drain of the transistor. As storage devices are continuously miniaturized with higher integration level, the size of the capacitor is continuously being reduced, and correspondingly, the size of the capacitor landing pad is also being reduced. However, in the fabrication process of the capacitor landing pad, some of the material making the capacitor landing pad will remain between adjacent capacitor landing pads during dry etching and pickling, causing interference between adjacent capacitor landing pads and potentially resulting in short circuits. Capacitors subsequently formed can also interfere with each other, thereby reducing the production yield of the memory, and affecting operational reliability and electrical performance of the memory.

### SUMMARY

The various embodiments of the present invention provide a semiconductor structure and a fabrication method therefor.

According to an aspect of the present invention, the various embodiments provide a semiconductor structure, including: a substrate, where a plurality of capacitor contact structures arranged at intervals are formed on the substrate; an isolation structure, where the isolation structure is disposed on the substrate and between adjacent capacitor contact structures, and a top surface of the isolation structure is not higher than a top surface of each capacitor contact structure; and an isolation groove, where the isolation groove extends from the top surface of the isolation structure to an interior of the isolation structure, and a spacing is provided between the isolation groove and the capacitor contact structure.

In some embodiments, the plurality of capacitor contact structures are arrayed in a plurality of rows and a plurality of columns, the plurality of the capacitor contact structures of a same column are arranged at intervals in a first direction, the plurality of the capacitor contact structures of a same row are arranged at intervals in a second direction, and the second direction intersects the first direction; and the isolation groove includes a plurality of first isolation grooves arranged at intervals, and the first isolation grooves extend in the first direction and are disposed between two adjacent columns of the capacitor contact structures.

In some embodiments, the isolation groove includes a plurality of second isolation grooves arranged at intervals, the second isolation grooves extend in the second direction, are disposed between two adjacent rows of the capacitor contact structures, and penetrate through a plurality of the first isolation grooves.

In some embodiments, the semiconductor structure further includes a plurality of capacitor structures, where the capacitor structures are disposed on the substrate, and are in contact with the capacitor contact structures in a one-to-one correspondence.

In some embodiments, the semiconductor structure further includes a support structure, where the support structure includes a first support layer, a second support layer, and a third support layer that are sequentially stacked from bottom to top, and the support structure includes a plurality of capacitor holes penetrating the first support layer, the second support layer, and the third support layer, where the capacitor holes are arranged in a one-to-one correspondence with the capacitor contact structures, and the capacitor holes expose the capacitor contact structures; where the isolation groove penetrates the first support layer in a thickness direction; and where the capacitor structure includes: a lower electrode, where the lower electrode is disposed on a sidewall and a bottom of the capacitor hole, is connected to each of the first support layer, the second support layer, and the third support layer, and is in contact with the capacitor contact structure; a capacitor dielectric layer, where the capacitor dielectric layer is disposed on a surface of the lower electrode and in the isolation groove; and an upper electrode, where the upper electrode is disposed on a surface of the capacitor dielectric layer.

In some embodiments, a gap is provided between the upper electrodes, and the capacitor structure further includes: a filling conductive layer for filling the gap.

According to another aspect of the present invention, the various embodiments further provide a method for fabricating a semiconductor structure, including: providing a substrate; forming a plurality of capacitor contact structures arranged at intervals on the substrate; filling a gap between adjacent capacitor contact structures with an isolation structure, where a top surface of the isolation structure is not higher than a top surface of each capacitor contact structure; and forming an isolation groove, where the isolation groove extends from the top surface of the isolation structure to an interior of the isolation structure, and a spacing is provided between the isolation groove and the capacitor contact structure.

In some embodiments, the plurality of capacitor contact structures are arrayed in a plurality of rows and a plurality of columns, the plurality of the capacitor contact structures of a same column are arranged at intervals in a first direction, the plurality of the capacitor contact structures of a same row are arranged at intervals in a second direction, and the second direction intersects the first direction; and where the forming an isolation groove includes: forming a first patterned mask layer on the capacitor contact structure and the isolation structure, where the first patterned mask layer includes a plurality of parallel first mask patterns arranged at intervals, the first mask patterns extend in a first direction, and an orthographic projection of a gap between adjacent first mask patterns on an upper surface of the substrate is located between two adjacent columns of the capacitor contact structures; and etching the isolation structure based on the first patterned mask layer to form a plurality of first isolation grooves arranged at intervals, where the first isolation grooves extend in the first direction and are disposed between two adjacent columns of the capacitor contact structures.

In some embodiments, the forming a first patterned mask layer on the substrate includes: forming a first mask layer on the capacitor contact structure and the isolation structure; forming, on an upper surface of the first mask layer, a plurality of parallel first submask patterns that are arranged at intervals and extend in the first direction; forming a first sacrificial pattern on a sidewall of the first submask pattern, and removing the first submask pattern to retain a plurality of parallel first sacrificial patterns that are arranged at intervals and extend in the first direction; forming a first filling mask layer, where the first filling mask layer fills a gap between adjacent first sacrificial patterns, and an upper surface of the first filling mask layer is not higher than an upper surface of the first sacrificial pattern; removing the first sacrificial pattern to form a first initial trench between adjacent first filling mask layers; and etching the first mask layer along the first initial trench to obtain the first patterned mask layer.

In some embodiments, the forming a first sacrificial pattern on a sidewall of the first submask pattern includes: forming a first sacrificial material layer on an upper surface of the first mask layer exposed between adjacent first submask patterns, the sidewall of the first submask pattern, and a top of the first submask pattern; and removing the first sacrificial material layer disposed on the upper surface of the first mask layer exposed between adjacent first submask patterns and on the top of the first submask pattern, and retaining the first sacrificial material layer disposed on the sidewall of the first submask pattern as the first sacrificial pattern.

In some embodiments, the forming a first filling mask layer includes: forming a first filling material layer on the first mask layer, where the first filling material layer fills a gap between adjacent first sacrificial patterns and covers the first sacrificial pattern; and etching the first filling material layer to remove the first filling material layer on a top of the first sacrificial pattern, and retaining the first filling material layer disposed between adjacent first sacrificial patterns to obtain the first filling mask layer.

In some embodiments, the forming an isolation groove further includes: forming a second patterned mask layer on the capacitor contact structure and the isolation structure, where the second patterned mask layer includes a plurality of parallel second mask patterns arranged at intervals, the second mask patterns extend in a second direction, the second direction intersects the first direction, and an orthographic projection of a gap between adjacent second mask patterns on an upper surface of the substrate is located between two adjacent rows of the capacitor contact structures; and etching the isolation structure based on the second patterned mask layer to form a plurality of second isolation grooves arranged at intervals, where the second isolation grooves extend in the second direction, are disposed between two adjacent rows of the capacitor contact structures, and penetrate through a plurality of the first isolation grooves.

In some embodiments, before the forming a first patterned mask layer and a second patterned mask layer on the capacitor contact structure and the isolation structure, the forming an isolation groove further includes: forming a pattern transfer material layer; before etching the isolation structure, transferring the first mask pattern and the second mask pattern to the pattern transfer material layer to form a pattern transfer layer; and etching the isolation structure based on the first patterned mask layer, the second patterned mask layer, and the pattern transfer layer to form the plurality of first isolation grooves arranged at intervals and the plurality of second isolation grooves arranged at intervals.

In some embodiments, after the forming an isolation groove, the method further includes: forming a plurality of capacitor structures on the substrate, where the capacitor structures are in contact with the capacitor contact structures in a one-to-one correspondence.

In some embodiments, the forming a plurality of capacitor structures on the substrate includes: forming a first support layer on an upper surface of the isolation structure, where the first support layer covers a top surface of the capacitor contact structure, and the isolation groove penetrates the first support layer in a thickness direction; after forming the isolation groove, forming a first capacitor sacrificial layer on the first support layer, where the first capacitor sacrificial layer fills the isolation groove; forming a second support layer on an upper surface of the first capacitor sacrificial layer; forming a second capacitor sacrificial layer on an upper surface of the second support layer; forming a third support layer on an upper surface of the second capacitor sacrificial layer; forming a plurality of capacitor holes, where the capacitor hole penetrates the third support layer, the second capacitor sacrificial layer, the second support layer, the first capacitor sacrificial layer, and the first support layer to expose the capacitor contact structure; forming a lower electrode on a sidewall and a bottom of the capacitor hole; removing the first capacitor sacrificial layer and the second capacitor sacrificial layer; forming a capacitor dielectric layer on a surface of the lower electrode and in the isolation groove; and forming an upper electrode on a surface of the capacitor dielectric layer.

In some embodiments, a gap is provided between the upper electrodes, and after the forming an upper electrode, the method further includes: forming a filling conductive layer, where the filling conductive layer fills at least the gap.

The embodiments of the present invention may/at least have the following advantages:

In the semiconductor structure provided in the embodiments of the present invention, the problem of short circuits between adjacent capacitor contact structures is alleviated by disposing an isolation structure between adjacent capacitor contact structures. In the fabrication process of the capacitor contact structure, the capacitor contact material used to form the capacitor contact structure is prone to oxidation and will remain between adjacent capacitor contact structures, causing interference between adjacent capacitor contact structures and resulting in short circuits. However, according to the semiconductor structure provided in the embodiments of the present invention, an isolation groove extending from the top surface of the isolation structure to the interior of the isolation structure is further disposed, thereby alleviating the problem of short circuits caused by interference between adjacent capacitor contact structures, resulting from the residue of oxidized capacitor contact material between adjacent capacitor contact structures. Capacitors subsequently formed do not interfere with each other either. Therefore, the semiconductor structure provided in the embodiments of the present invention can improve the production yield and operational reliability of the capacitor, thereby improving the production yield and electrical performance of the semiconductor structure.

In the method for fabricating a semiconductor structure provided in the embodiments of the present invention, the problem of short circuits between adjacent capacitor contact structures is alleviated by filling the gap between adjacent capacitor contact structures with an isolation structure. In the fabrication process of the capacitor contact structure, the capacitor contact material used to form the capacitor contact structure is prone to oxidation and will remain between adjacent capacitor contact structures, causing interference between adjacent capacitor contact structures and resulting in short circuits. However, according to the method for fabricating a semiconductor structure provided in the embodiments of the present invention, an isolation groove extending from the top surface of the isolation structure to the interior of the isolation structure is further formed, thereby alleviating the problem of short circuits caused by interference between adjacent capacitor contact structures, resulting from the residue of the capacitor contact material between adjacent capacitor contact structures. Capacitors subsequently formed do not interfere with each other either. Therefore, the method for fabricating a semiconductor structure provided in the embodiments of the present invention can improve the production yield and operational reliability of a capacitor, thereby improving the production yield and electrical performance of the semiconductor structure.

Details of one or more embodiments of the present invention are provided in the following accompanying drawings and descriptions. Other features, objectives, and advantages of some embodiments of the present invention become clear in the specification, accompanying drawings, and claims.

### BRIEF DESCRIPTION OF DRAWINGS

To describe technical solutions in some embodiments of the present invention more clearly, the following briefly describes the accompanying drawings needed for describing the embodiments. It is apparent that the accompanying drawings in the following description show merely some embodiments of the present invention, and a person of ordinary skill in the art may still derive other drawings from these accompanying drawings without creative efforts.

FIG. 1 to FIG. 5 are schematic flowcharts of a method for fabricating a semiconductor structure according to some embodiments of the present invention;

FIG. 6 is a schematic diagram of a cross-sectional view of a structure obtained in step S300 in a method for fabricating a semiconductor structure according to some embodiments of the present invention;

FIG. 7A and FIG. 8A are schematic diagrams of a cross-sectional view of a structure obtained in step S413 in a method for fabricating a semiconductor structure according to some embodiments of the present invention; FIG. 7B and FIG. 8B are schematic diagrams of a top-view structure of a structure obtained in step S413 in a method for fabricating a semiconductor structure according to some embodiments of the present invention;

FIG. 9 and FIG. 10A are schematic diagrams of a cross-sectional view of a structure obtained in step S414 in a method for fabricating a semiconductor structure according to some embodiments of the present invention; FIG. 10B is a schematic diagram of a top-view structure of a structure obtained in step S414 in a method for fabricating a semiconductor structure according to some embodiments of the present invention;

FIG. 11A is a schematic diagram of a cross-sectional view of a structure obtained in step S415 in a method for fabricating a semiconductor structure according to some embodiments of the present invention; FIG. 11B is a schematic diagram of a top-view structure of a structure obtained in step S415 in a method for fabricating a semiconductor structure according to some embodiments of the present invention;

FIG. 12 is a schematic diagram of a cross-sectional view of a structure obtained in step S416 in a method for fabricating a semiconductor structure according to some embodiments of the present invention;

FIG. 13A is a schematic diagram of a cross-sectional view of a structure obtained in step S400 in a method for fabricating a semiconductor structure according to some embodiments of the present invention; FIG. 13B is a schematic diagram of a top-view structure of a structure obtained in step S400 in a method for fabricating a semiconductor structure according to some embodiments of the present invention;

FIG. 14 to FIG. 22 are schematic diagrams of a cross-sectional view of a structure obtained in a method for fabricating a semiconductor structure according to some embodiments of the present invention; and FIG. 22 is also a schematic diagram of a cross-sectional view of a semiconductor structure according to some embodiments of the present invention.

### DESCRIPTION OF EMBODIMENTS

To facilitate understanding of the embodiments of the present invention, the following describes some embodiments of the present invention in more detail with reference to related accompanying drawings. The accompanying drawings show some exemplary embodiments of the present invention. However, the embodiments of the present invention can be implemented in many different forms and are not limited to the embodiments described herein. On the contrary, these embodiments are provided to make the content disclosed in some embodiments of the present invention more thorough and comprehensive.

Unless otherwise specified, all technical and scientific terms used in this specification have the same meanings as those usually understood by a person skilled in the art of some embodiments of the present invention. Terms used in this specification of some embodiments of the present invention are merely intended to describe some specific embodiments, but not to limit the embodiments of the present invention.

It should be understood that when an element or a layer is referred to as “disposed above . . . ”, “between adjacent . . . ”, or “connected to . . . ”, the element or the layer may be directly disposed above another element or layer, between adjacent elements or layers, or connected to the another element or layer, or there may exist an intermediate element or layer. It should be understood that although terms “first”, “second”, “third”, etc. may be used to describe various elements, components, regions, layers, doping types and/or portions, these elements, components, regions, layers, doping types and/or portions should not be limited by these terms. These terms are used merely to distinguish one element, component, region, layer, doping type or portion from another element, component, region, layer, doping type or portion. Therefore, the first element, component, region, layer, doping type or portion discussed below may be represented as a second element, component, region, layer or portion without departing from the teachings of some embodiments of the present invention. For example, a first isolation groove may be referred to as a second isolation groove, and similarly, a second isolation groove may be referred to as a first isolation groove. The first isolation groove and the second isolation groove are different isolation grooves.

It should be further understood that, in addition to the orientations shown in the figures, the spatial relationship terms further include different orientations of the devices in use and operation. For example, if a device in the drawings is flipped, an “upper surface” described should be oriented as a “lower surface”. Therefore, the example term “upper” may include two orientations of “upper” and “lower”. In addition, the device may alternatively include additional orientations (e.g., rotation by 90 degrees or other orientations), and the spatial relationship terms used herein are interpreted accordingly.

As used herein, the singular forms of “a/an”, “one”, and “the/said” may also include the plural forms, unless otherwise specified in the context clearly. It should be further understood that, when the terms “comprise” and/or “include” are used in this specification, presence of the features, entireties, steps, operations, elements and/or components may be determined, without excluding presence or addition of one or more of other features, entireties, steps, operations, elements, components and/or their combinations. In addition, as used herein, the term “and/or” includes any or all combinations of related listed items.

Some embodiments of the present invention are described herein with reference to a schematic cross-sectional view of some desired embodiments (and intermediate structures) of the embodiments of the present invention, so that variations in the illustrated shapes caused by, for example, manufacturing techniques and/or tolerances may be anticipated. Therefore, some embodiments of the present invention should not be limited to the particular shapes of the regions shown herein, but include shape deviations caused by, for example, manufacturing techniques. The regions shown in the figures are illustrative in nature and their shapes do not represent the actual shapes of the regions of the device and do not limit the scope of some embodiments of the present invention.

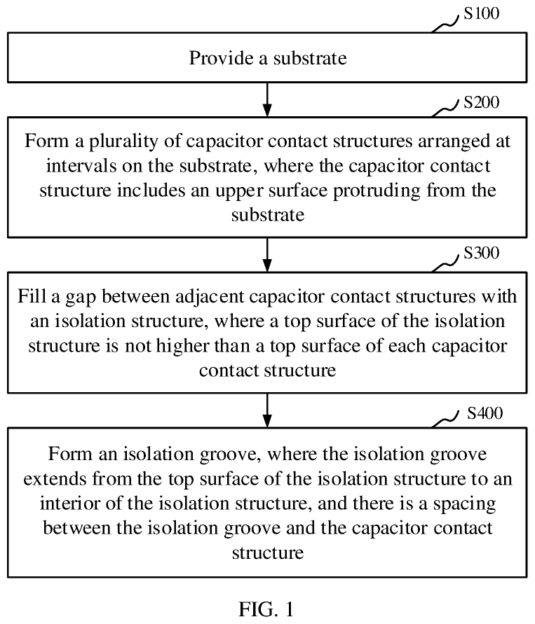

References are made to FIG. 1 to FIG. 22. It should be noted that, the illustrations provided in the embodiments of the present invention merely describe the basic concept of some embodiments of the present invention by using examples. Although the drawings show only components related to some embodiments of the present invention, and are not drawn based on a quantity of components, a shape of a component, and a size of a component during actual implementation, a shape, a quantity, and a scale of the components may be arbitrarily changed during actual implementation, and a component layout form may be more complex.

Some embodiments of the present invention provide a method for fabricating a semiconductor structure.

Referring to FIG. 1, in some embodiments, the method for fabricating a semiconductor structure may include the following steps:
S100: Provide a substrate.
S200: Form a plurality of capacitor contact structures arranged at intervals on the substrate, where the capacitor contact structure includes an upper surface protruding from the substrate.
S300: Fill a gap between adjacent capacitor contact structures with an isolation structure, where a top surface of the isolation structure is not higher than a top surface of each capacitor contact structure.
S400: Form an isolation groove, where the isolation groove extends from the top surface of the isolation structure to an interior of the isolation structure, and a spacing is provided between the isolation groove and the capacitor contact structure.

According to the method for fabricating a semiconductor structure provided in the above-mentioned embodiments, the problem of short circuits between adjacent capacitor contact structures is alleviated by filling the gap between adjacent capacitor contact structures with an isolation structure. In the fabrication process of the capacitor contact structure, the capacitor contact material used to form the capacitor contact structure is prone to oxidation and will remain between adjacent capacitor contact structures, causing interference between adjacent capacitor contact structures and resulting in short circuits. However, according to the method for fabricating a semiconductor structure provided in the embodiments of the present invention, an isolation groove extending from the top surface of the isolation structure to the interior of the isolation structure is further formed, thereby alleviating the problem of short circuits caused by interference between adjacent capacitor contact structures, resulting from the residue of the capacitor contact material between adjacent capacitor contact structures. Capacitors subsequently formed do not interfere with each other either. Therefore, the method for fabricating a semiconductor structure provided in the embodiments of the present invention can improve the production yield and operational reliability of a capacitor, thereby improving the production yield and electrical performance of the semiconductor structure.

In some embodiments, the plurality of capacitor contact structures are arrayed in a plurality of rows and a plurality of columns. The plurality of the capacitor contact structures in the same column are arranged at intervals in a first direction, the plurality of the capacitor contact structures in the same row are arranged at intervals in a second direction, and the second direction intersects the first direction.

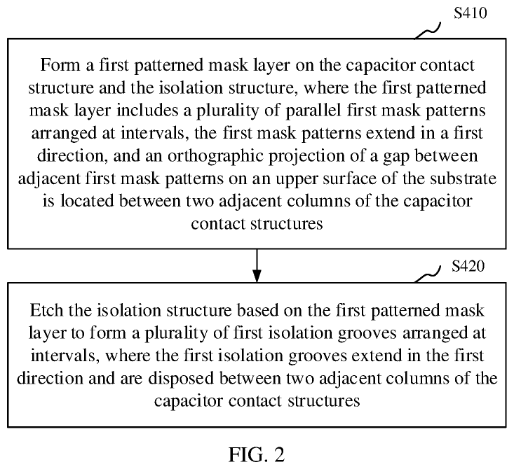

Referring to FIG. 2, in some embodiments, step S400 of forming an isolation groove may include the following steps:
S410: Form a first patterned mask layer on the capacitor contact structure and the isolation structure, where the first patterned mask layer includes a plurality of parallel first mask patterns arranged at intervals, the first mask patterns extend in a first direction, and an orthographic projection of a gap between adjacent first mask patterns on an upper surface of the substrate is located between two adjacent columns of the capacitor contact structures.
S420: Etch the isolation structure based on the first patterned mask layer to form a plurality of first isolation grooves arranged at intervals, where the first isolation grooves extend in the first direction and are disposed between two adjacent columns of the capacitor contact structures.

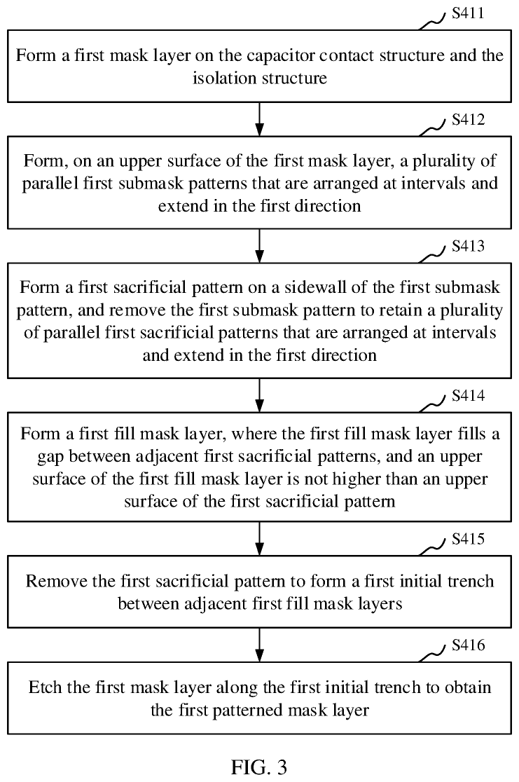

Referring to FIG. 3, in some embodiments, step S410 of forming a first patterned mask layer on the substrate may include the following steps:
S411: Form a first mask layer on the capacitor contact structure and the isolation structure.
S412: Form, on an upper surface of the first mask layer, a plurality of parallel first submask patterns that are arranged at intervals and extend in the first direction.
S413: Form a first sacrificial pattern on a sidewall of the first submask pattern, and remove the first submask pattern to retain a plurality of parallel first sacrificial patterns that are arranged at intervals and extend in the first direction.
S414: Form a first filling mask layer, where the first filling mask layer fills a gap between adjacent first sacrificial patterns, and an upper surface of the first filling mask layer is not higher than an upper surface of the first sacrificial pattern.
S415: Remove the first sacrificial pattern to form a first initial trench between adjacent first filling mask layers.
S416: Etch the first mask layer along the first initial trench to obtain the first patterned mask layer.

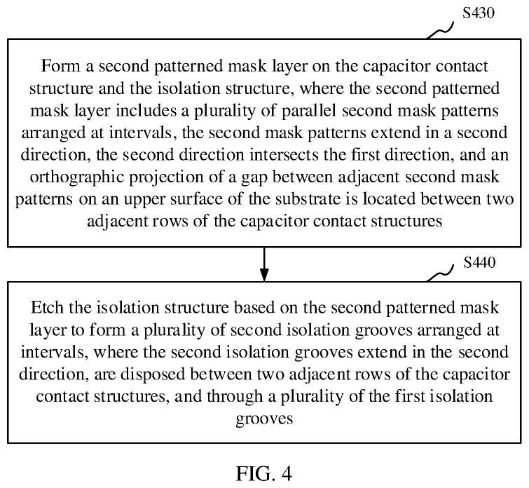

Referring to FIG. 4, in some embodiments, step S400 of forming an isolation groove may further include the following steps:
S430: Form a second patterned mask layer on the capacitor contact structure and the isolation structure, where the second patterned mask layer includes a plurality of parallel second mask patterns arranged at intervals, the second mask patterns extend in a second direction, the second direction intersects the first direction, and an orthographic projection of a gap between adjacent second mask patterns on an upper surface of the substrate is located between two adjacent rows of the capacitor contact structures.
S440: Etch the isolation structure based on the second patterned mask layer to form a plurality of second isolation grooves arranged at intervals; the second isolation grooves, extending in the second direction, are disposed between two adjacent rows of the capacitor contact structures, and penetrate through a plurality of the first isolation grooves.

In some embodiments, after step S400 of forming an isolation groove, the method further includes the step of forming a plurality of capacitor structures on the substrate. The capacitor structures are in contact with the capacitor contact structures in a one-to-one correspondence.

In some embodiments, before step S400 of forming an isolation groove, the method further includes the step of forming a first support layer on an upper surface of the isolation structure.

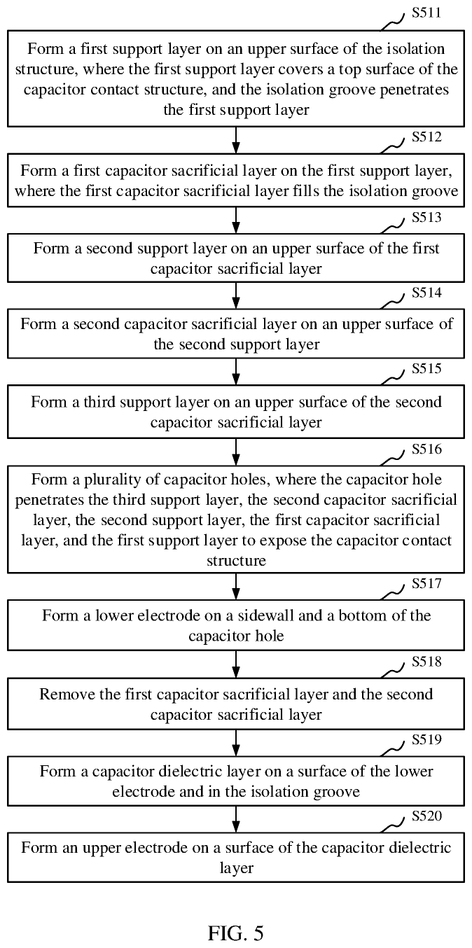

Referring to FIG. 5, in some embodiments, after step S400 of forming an isolation groove, the following steps may be used to form a plurality of capacitor structures, including:
S511: Form a first support layer on an upper surface of the isolation structure, where the first support layer covers a top surface of the capacitor contact structure, and the isolation groove penetrates the first support layer in the thickness direction.
S512: After forming the isolation groove, form a first capacitor sacrificial layer on the first support layer, where the first capacitor sacrificial layer fills the isolation groove.
S513: Form a second support layer on an upper surface of the first capacitor sacrificial layer.
S514: Form a second capacitor sacrificial layer on an upper surface of the second support layer.
S515: Form a third support layer on an upper surface of the second capacitor sacrificial layer.
S516: Form a plurality of capacitor holes, where the capacitor hole penetrates the third support layer, the second capacitor sacrificial layer, the second support layer, the first capacitor sacrificial layer, and the first support layer to expose the capacitor contact structure.
S517: Form a lower electrode on a sidewall and a bottom of the capacitor hole.
S518: Remove the first capacitor sacrificial layer and the second capacitor sacrificial layer.
S519: Form a capacitor dielectric layer on a surface of the lower electrode and in the isolation groove.
S520: Form an upper electrode on a surface of the capacitor dielectric layer.

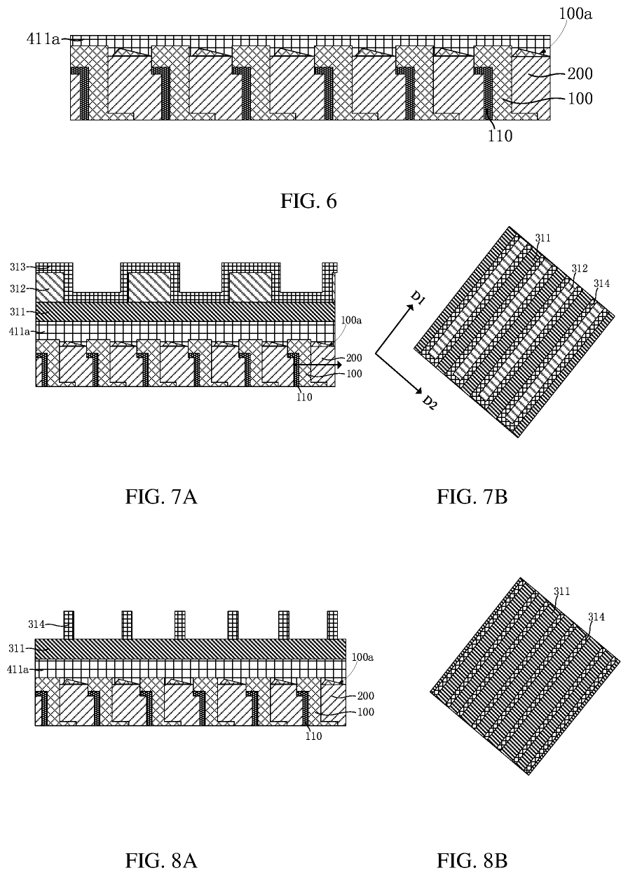

To describe the fabrication method in some embodiments of the present invention more clearly, the following describes some embodiments of the present invention with reference to FIG. 6 to FIG. 22.

In step S100, a substrate is provided.

The material of the substrate is not specifically limited in some embodiments of the present invention. In some examples, the material of the substrate may include but is not limited to silicon (Si), germanium (Ge), silicon germanium (SiGe), silicon carbide (SiC), or a combination thereof.

Referring to FIG. 6, in step S200, a plurality of capacitor contact structures 100 arranged at intervals are formed on the substrate (not shown in FIG. 6). As shown in FIG. 6, an upper surface of the capacitor contact structure 100 may protrude from an upper surface of the substrate.

The material of the capacitor contact structure 100 is not specifically limited in some embodiments of the present invention. In some examples, the material of the capacitor contact structure 100 may include but is not limited to a related semiconductor conductive material such as tungsten (W) or copper (Cu).

In some embodiments, a sidewall dielectric layer 110 may be formed on a sidewall of at least one side of the capacitor contact structure 100.

In the fabrication method provided in the above-mentioned embodiments, the sidewall dielectric layer 110 may be formed to prevent the capacitor contact structure 100 from diffusing in a high-temperature environment so as to avoid interference between adjacent capacitor contact structures 100 and avoid short circuits. As such, the problem of short circuits is avoided between adjacent capacitors subsequently formed, thereby further improving a production yield and operational reliability of a product obtained by using the fabrication method.

The material of the sidewall dielectric layer 110 is not specifically limited in some embodiments of the present invention. In some examples, the material of the sidewall dielectric layer 110 may include but is not limited to metal silicide.

Still referring to FIG. 6, in step S300, fill a gap between adjacent capacitor contact structures 100 with an isolation structure 200. As shown in FIG. 6, a top surface of the isolation structure 200 is not higher than the top surface of each capacitor contact structure 100, so that the top surface of the capacitor contact structure 100 is exposed.

In some embodiments of the present invention, a gap between adjacent capacitor contact structures 100 may be filled with an isolation structure 200, so that adjacent capacitor contact structures 100 are insulated to avoid short circuits.

The material of the isolation structure 200 is not specifically limited in some embodiments of the present invention. In some examples, the material of the isolation structure 200 may include but is not limited to an insulating material such as silicon dioxide (SiO₂) or silicon nitride (SiN).

Referring to FIG. 7 to FIG. 12, in step S400, an isolation groove 300 is formed. The isolation groove 300 extends from the top surface of the isolation structure 200 to the interior of the isolation structure 200 and is spaced from the capacitor contact structure 100.

It can be seen from FIG. 12 that, in some embodiments of the present invention, the isolation groove 300 can effectively truncate a capacitor contact material 100a that remains between adjacent capacitor contact structures 100. As such, the remaining capacitor contact material 100a does not cause interference between adjacent capacitor contact structures 100, thereby alleviating the problem of short circuits. Capacitors subsequently formed do not interfere with each other.

In some embodiments, the plurality of capacitor contact structures 100 are arrayed in a plurality of rows and a plurality of columns, the plurality of the capacitor contact structures 100 of a same column are arranged at intervals in a first direction D1, and the plurality of the capacitor contact structures 100 of a same row are arranged at intervals in a second direction D2.

In some embodiments of the present invention, the second direction D2 intersects the first direction D1.

In some embodiments, the isolation groove 300 formed in step S400 may include a plurality of first isolation grooves arranged at intervals.

In some examples, step S400 may specifically include the following steps S410 to S420, so as to form the first isolation groove.

In step S410, referring to FIG. 7 to FIG. 12, a first patterned mask layer 310 is formed on the capacitor contact structure 100 and the isolation structure 200.

The first patterned mask layer 310 may include a plurality of parallel first mask patterns arranged at intervals. The first mask patterns extend in a first direction, and an orthographic projection of a gap between adjacent first mask patterns on an upper surface of the substrate should be located between two adjacent columns of the capacitor contact structures 100.

In step S420, still referring to FIG. 7 to FIG. 12, the isolation structure 200 is etched based on the first patterned mask layer 310 to form a plurality of first isolation grooves arranged at intervals.

The first isolation grooves extend in the first direction D1 and are disposed between two adjacent columns of the capacitor contact structures 100.

In some embodiments, the isolation groove 300 formed in step S400 may further include a plurality of second isolation grooves arranged at intervals.

In some embodiments, step S400 may specifically further include the following steps S430 and S440, so as to form the second isolation groove.

In step S430, a second patterned mask layer is formed on the capacitor contact structure 100 and the isolation structure 200.

The second patterned mask layer may include a plurality of parallel second mask patterns arranged at intervals, the second mask patterns extend in a second direction, the second direction intersects the first direction, and an orthographic projection of a gap between adjacent second mask patterns on an upper surface of the substrate is located between two adjacent rows of the capacitor contact structures 100.

In step S440, the isolation structure 200 is etched based on the second patterned mask layer to form a plurality of second isolation grooves arranged at intervals.

The second isolation grooves extend in the second direction D2, are disposed between two adjacent rows of the capacitor contact structures 100, and penetrate through a plurality of the first isolation grooves.

In some embodiments, a second patterned mask layer may be formed after the first patterned mask layer 310 is formed.

It should be noted that in some embodiments of the present invention, there is no limitation on a sequence between the step of forming a first isolation groove and the step of forming a second isolation groove. In other words, either of the two steps may be performed before the other step, or the two steps may be performed simultaneously.

In some examples, materials of the first patterned mask layer 310 and the second patterned mask layer each may include but are not limited to silicon oxynitride (SiOxNy).

In some embodiments, the first isolation grooves and the second isolation grooves may be formed by using the following method. For example, a pattern transfer material layer is formed before the first patterned mask layer 310 and the second patterned mask layer are formed. Before the isolation structure 200 is etched, the first mask pattern and the second mask pattern are transferred to the pattern transfer material layer to form a pattern transfer layer.

The isolation structure 200 is etched based on the first patterned mask layer 310, the second patterned mask layer, and the pattern transfer layer to form the plurality of first isolation grooves arranged at intervals and the plurality of second isolation grooves arranged at intervals.

In some examples, step S410 may specifically include the following steps S411 to S416.

In step S411, as shown in FIG. 7A and FIG. 7B, the first mask layer 311 is formed on the capacitor contact structure 100 and the isolation structure 200.

In step S412, as shown in FIG. 7A and FIG. 7B, a plurality of parallel first submask patterns 312 that are arranged at intervals and extend in the first direction are formed on an upper surface of the first mask layer 311.

In step S413, a first sacrificial pattern 314 is formed on a sidewall of the first submask pattern 312, and the first submask pattern 312 is removed, as shown in FIG. 8A and FIG. 8B, to retain a plurality of parallel first sacrificial patterns 314 that are arranged at intervals and extend in the first direction.

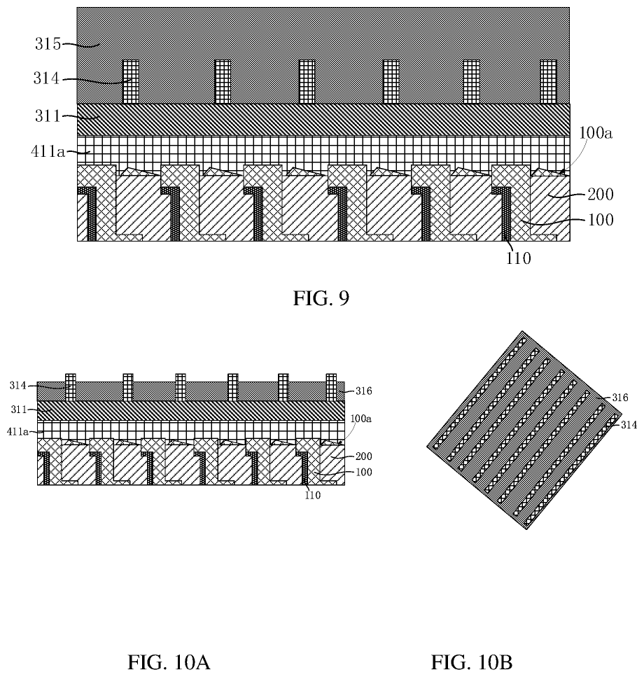

In step S414, as shown in FIG. 9 and FIG. 10, a first filling mask layer 316 is formed, where the first filling mask layer 316 fills a gap between adjacent first sacrificial patterns 314, and an upper surface of the first filling mask layer 316 is not higher than an upper surface of the first sacrificial pattern 314.

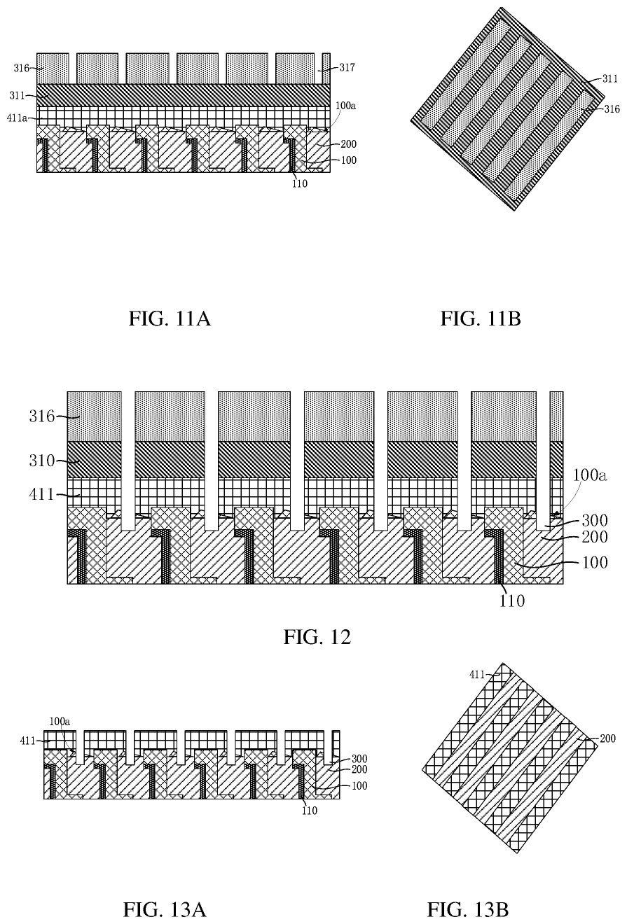

In step S415, as shown in FIG. 11A and FIG. 11B, the first sacrificial pattern 314 is removed to form a first initial trench 317 between adjacent first filling mask layers 316.

In step S416, as shown in FIG. 12, the first mask layer 311 is etched along the first initial trench 317 to obtain the first patterned mask layer 310.

The material of the first submask pattern 312 formed in step S412 is not specifically limited in some embodiments of the present invention. In some examples, the material of the first submask pattern 312 may include but is not limited to photoresist.

With respect to step S413, in some embodiments, the first sacrificial pattern 314 may be formed by using the following steps, including:

As shown in FIG. 7A, a first sacrificial material layer 313 is formed on an upper surface of the first mask layer 311 exposed between adjacent first submask patterns 312, the sidewall of the first submask pattern 312, and a top of the first submask pattern 312.

As shown in FIG. 7B, the first sacrificial material layer 313 disposed on the upper surface of the first mask layer 311 exposed between adjacent first submask patterns 312 and on the top of the first submask pattern 312 is removed, and the first sacrificial material layer 313 disposed on the sidewall of the first submask pattern 312 is retained as the first sacrificial pattern 314.

In some examples, the material of the first sacrificial pattern 314 may include but is not limited to an oxide.

A method for removing a portion of the first sacrificial material layer 313 in the above-mentioned step is not specifically limited in some embodiments of the present invention. In some examples, a portion of the first sacrificial material layer 313 may be removed through etching by using a carbon tetrafluoride (also referred to as tetrafluoromethane, whose chemical formula is CF₄) gas or a perfluorobutadiene (C₄F₆) gas.

The step of removing the first submask pattern 312 may be further included between step S413 and step S414.

In some examples, the first submask pattern 312 may be removed through, without limitation to, dry cleaning by using an oxygen (02) plasma or silicon dioxide.

With respect to step S414, in some embodiments, the first filling mask layer 316 may be formed by using the following steps, including:

As shown in FIG. 9, a first filling material layer 315 is formed on the first mask layer 311. The first filling material layer 315 should fill at least a gap between adjacent first sacrificial patterns 314. Optionally, the first filling material layer 315 may further cover the first sacrificial pattern 314.

As shown in FIG. 10A and FIG. 10B, the first filling material layer 315 is etched to remove the first filling material layer 315 on a top of the first sacrificial pattern 314, and the first filling material layer 315 disposed between adjacent first sacrificial patterns 314 is retained, so as to obtain the first filling mask layer 316.

A method for removing the first sacrificial pattern 314 in step S415 is not specifically limited in some embodiments of the present invention. In some examples, the first sacrificial pattern 314 may be removed by using a wet etching process.

The material of the first filling mask layer 316 formed in the above-mentioned step is not specifically limited in some embodiments of the present invention. In some examples, the material of the first filling mask layer 316 may include but is not limited to a carbide (Carbon).

It may be understood that in some embodiments of the present invention, for a method for forming the second patterned mask layer in step S430, references may be made to the above-mentioned step of forming the first patterned mask layer 310, and details are not described herein again.

Referring to FIG. 13A and FIG. 13B, in some embodiments, the first patterned mask layer 310 and the first filling mask layer 316 may be removed after the isolation groove 300 is formed.

Referring to FIG. 14 to FIG. 22, in some embodiments, a plurality of capacitor structures 400 may be formed on the substrate after the isolation groove 300 is formed in step S400.

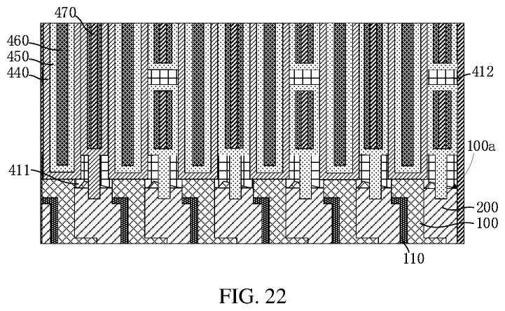

As shown in FIG. 22, the capacitor structures 400 may be in contact with the capacitor contact structures 100 in a one-to-one correspondence.

In some examples, forming the capacitor structure 400 may specifically include the following steps S511 to S520.

In step S511, referring to FIG. 13, a first support layer 411 is formed on an upper surface of the isolation structure 200, where the first support layer 411 covers a top surface of the capacitor contact structure 100, and the isolation groove 300 penetrates the first support layer 411.

In step S512, referring to FIG. 14, a first capacitor sacrificial layer 421 is formed on the first support layer 411, where the first capacitor sacrificial layer 421 fills the isolation groove 300.

In step S513, still referring to FIG. 14, a second support layer 412 is formed on an upper surface of the first capacitor sacrificial layer 421.

In step S514, still referring to FIG. 14, a second capacitor sacrificial layer 422 is formed on an upper surface of the second support layer 412.

In step S515, still referring to FIG. 14, a third support layer 413 is formed on an upper surface of the second capacitor sacrificial layer 422.

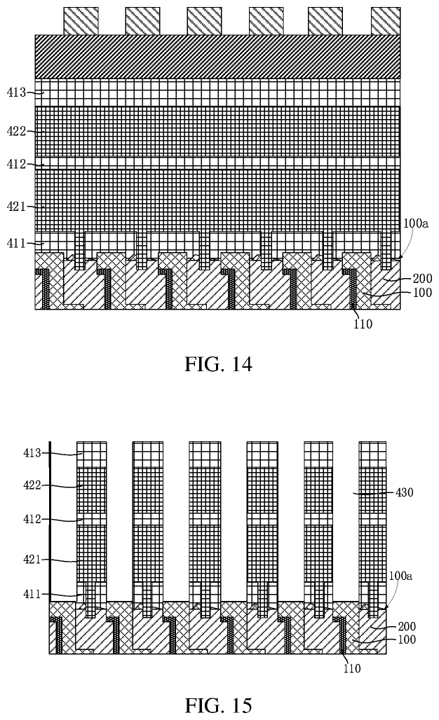

In step S516, referring to FIG. 15, a plurality of capacitor holes 430 are formed. The capacitor hole 430 penetrates the third support layer 413, the second capacitor sacrificial layer 422, the second support layer 412, the first capacitor sacrificial layer 421, and the first support layer 411 to expose the capacitor contact structure 100.

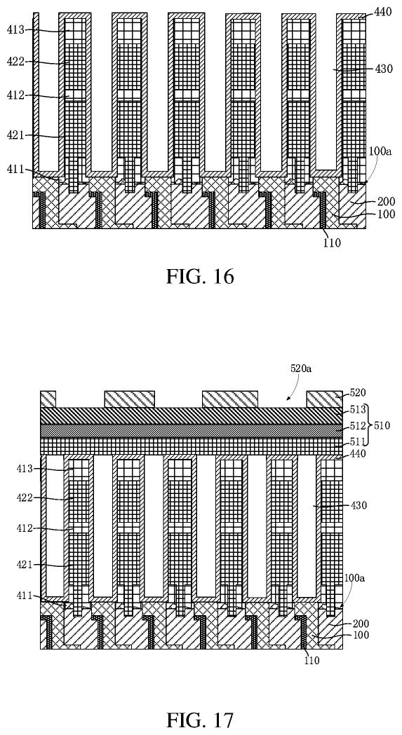

In step S517, referring to FIG. 16, a lower electrode 440 is formed on a sidewall and a bottom of the capacitor hole 430.

In step S518, referring to FIG. 17 to FIG. 21, the first capacitor sacrificial layer 421 and the second capacitor sacrificial layer 422 are removed.

In step S519, referring to FIG. 22, a capacitor dielectric layer 450 is formed on a surface of the lower electrode 440 and in the isolation groove 300.

In step S520, referring to FIG. 22, an upper electrode 460 is formed on a surface of the capacitor dielectric layer 450.

For ease of description, in some embodiments of the present invention, a surface, disposed above the third support layer 413, of the lower electrode 440 is referred to as a top surface of the lower electrode 440.

In some embodiments, step S511 may specifically include the following steps. For example, as shown in FIG. 6 to FIG. 11, before the isolation groove 300 is formed, a first support material layer 411a is formed on an upper surface of the isolation structure 200. The first support material layer 411a covers a top surface of the capacitor contact structure 100.

As shown in FIG. 12 and FIG. 13, in a process of forming the isolation groove 300, the isolation groove 300 penetrates the first support material layer 411a. The retained first support material layer 411a serves as the first support layer 411.

Neither the material of the first support layer 411 formed in step S511 nor the material of the second support layer 412 formed in step S513 is specifically limited in some embodiments of the present invention.

In some embodiments, the material of the first support layer 411 and the material of the second support layer 412 each include silicon nitride.

Neither the material of the first capacitor sacrificial layer 421 formed in step S512 nor the material of the second capacitor sacrificial layer 422 formed in step S514 is specifically limited in some embodiments of the present invention.

In some examples, the material of the first capacitor sacrificial layer 421 may include but is not limited to phosphosilicate glass (PSG), boron-phosphorosilicate glass (BPSG), and the like.

In some examples, the material of the second capacitor sacrificial layer 422 may include but is not limited to an oxide.

None of materials of the lower electrode 440, the capacitor dielectric layer 450, and the upper electrode 460 that are formed in the above-mentioned steps is specifically limited in some embodiments of the present invention.

In some examples, the material of the lower electrode 440 may include but is not limited to a compound formed by one or two of metal nitride and metal silicide.

In some examples, the material of the capacitor dielectric layer 450 may include but is not limited to zirconia (ZrOₓ), hafnium oxide (HfOₓ), zirconium titanium oxide (ZrTiOₓ), ruthenium oxide (RUOₓ), antimony oxide (SbOₓ), alumina (AlOₓ), or a combination thereof.

In some examples, the material of the upper electrode 460 may include but is not limited to polycrystalline silicon.

In some embodiments, step S518 may specifically include the following steps. For example, as shown in FIG. 17, a mask stack 510 is formed. The mask stack 510 covers the top surface of the lower electrode 440 and seals the capacitor hole 430.

Still referring to FIG. 17, a photoresist layer 520 is formed on an upper surface of the mask stack 510, and the photoresist layer 520 is patterned to form a photoresist pattern 520a on the photoresist layer 520. The photoresist pattern 520a exposes a portion of the upper surface of the mask stack 510.

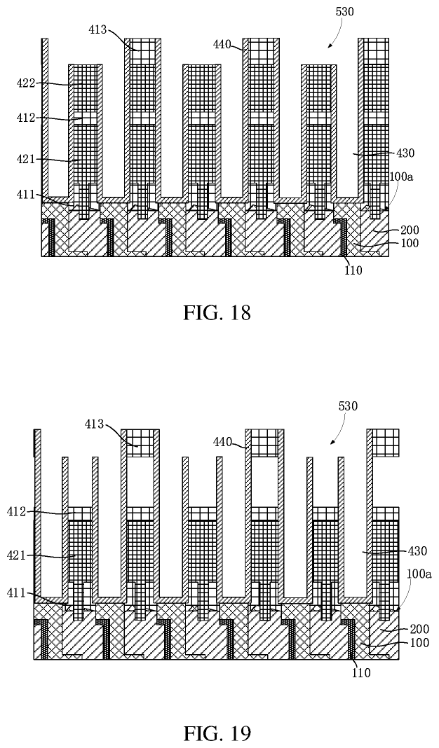

The mask stack 510 is etched based on the photoresist layer 520, so that a plurality of openings are formed in the mask stack 510, where the openings expose a portion of the third support layer 413. As shown in FIG. 18, the top surface of the lower electrode 440 is removed, and a pattern of the openings is transferred to the third support layer 413 to form a capacitor opening hole 530. The capacitor opening hole 530 exposes a portion of the second capacitor sacrificial layer 422.

As shown in FIG. 19, the second capacitor sacrificial layer 422 is removed to expose the second support layer 412.

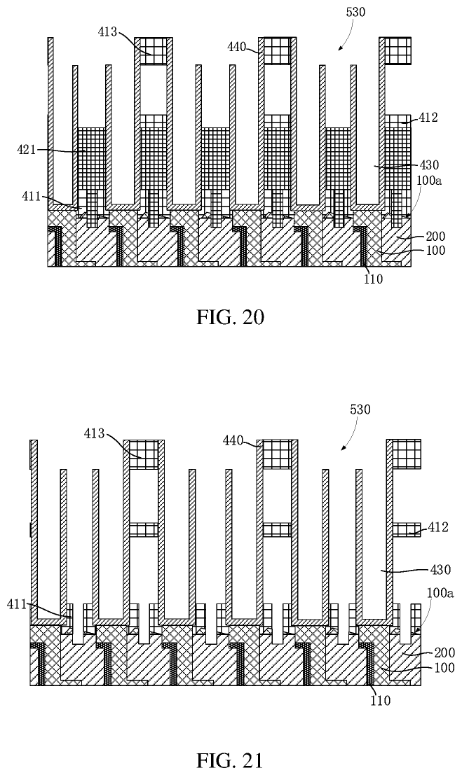

As shown in FIG. 20, a pattern of the capacitor opening hole 530 is transferred to the second support layer 412 to expose a portion of the first capacitor sacrificial layer 421.

As shown in FIG. 21, the first capacitor sacrificial layer 421 is removed to expose the first support layer 411.

A structure of the mask stack 510 is not specifically limited in some embodiments of the present invention.

Still referring to FIG. 17, in some embodiments, the mask stack 510 may include a first mask material layer 511, a second mask material layer 512, and a third mask material layer 513 that are sequentially stacked from bottom to top.

In some examples, the first mask material layer 511 may include but is not limited to a silicon dioxide layer. The second mask material layer 512 may include but is not limited to a crystalline carbon layer, an amorphous carbon layer, or the like. The third mask material layer 513 may include but is not limited to a silicon oxynitride layer.

Methods for removing the second capacitor sacrificial layer 422 and the first capacitor sacrificial layer 421 are not specifically limited in some embodiments of the present invention.

In some examples, the second capacitor sacrificial layer 422 may be removed by using the following steps: for example, after the capacitor opening hole 530 exposes a portion of the second capacitor sacrificial layer 422, acid solution is injected into the second capacitor sacrificial layer 422 through the capacitor opening hole 530, and the second capacitor sacrificial layer 422 is dissolved and removed by using the acid solution.

In some examples, the first capacitor sacrificial layer 421 may be removed by using the following steps: for example, after the pattern of the capacitor opening hole 530 is transferred to the second support layer 412, and a portion of the first capacitor sacrificial layer 421 is exposed, acid solution is injected into the first capacitor sacrificial layer 421, and the first capacitor sacrificial layer 421 is dissolved and removed by using the acid solution.

In some embodiments, a gap is provided between upper electrodes 460.

In some examples, still referring to FIG. 22, after the upper electrode 460 is formed in step S520, a step of forming a filling conductive layer 470 may be further included.

The filling conductive layer 470 may fill at least the gap between the upper electrodes 460 in some embodiments of the present invention.

It should be understood that although the steps in the flowcharts of FIG. 1 to FIG. 5 are shown in sequence indicated by arrows, these steps are not necessarily performed in such sequences. Unless expressly stated herein, these steps are not limited to a strict execution sequence, and may be performed in another sequence. In addition, at least some of the steps in FIG. 1 to FIG. 5 may include a plurality of steps or stages. These steps or stages are not necessarily performed and completed at the same moment, but may be performed at different moments. These steps or stages are not necessarily performed in sequence, either, but may be performed in turn or alternately with other steps or at least some steps or stages of the other steps.

Some embodiments of the present invention further provide a semiconductor structure.

Still referring to FIG. 22, in some embodiments, the semiconductor structure may include a substrate, an isolation structure 200, and an isolation groove 300.

A plurality of capacitor contact structures 100 arranged at intervals are formed on the substrate. The isolation structure 200 is disposed on the substrate and between adjacent capacitor contact structures 100, and a top surface of the isolation structure 200 should not be higher than a top surface of the capacitor contact structure 100. The isolation groove 300 extends from the top surface of the isolation structure 200 to an interior of the isolation structure 200, and a spacing is provided between the isolation groove 300 and the capacitor contact structure 100.

In the semiconductor structure provided in the above-mentioned embodiments, the problem of short circuits between adjacent capacitor contact structures 100 is alleviated by disposing an isolation structure 200 between adjacent capacitor contact structures 100. In the fabrication process of the capacitor contact structure 100, the capacitor contact material used to form the capacitor contact structure 100 is prone to oxidation and will remain between adjacent capacitor contact structures 100, causing interference between adjacent capacitor contact structures 100 and resulting in short circuits. However, according to the semiconductor structure provided in the embodiments of the present invention, an isolation groove 300 extending from the top surface of the isolation structure 200 to the interior of the isolation structure 200 is further disposed, thereby alleviating the problem of short circuits caused by interference between adjacent capacitor contact structures 100, resulting from the residue of the capacitor contact material between adjacent capacitor contact structures 100. Capacitors subsequently formed do not interfere with each other either. Therefore, the semiconductor structure provided in the embodiments of the present invention can improve the production yield and operational reliability of the capacitor, thereby improving the production yield and electrical performance of the semiconductor structure.

In some embodiments, the plurality of capacitor contact structures 100 are arrayed in a plurality of rows and a plurality of columns. The plurality of the capacitor contact structures in the same column are arranged at intervals in a first direction. The plurality of the capacitor contact structures in the same row are arranged at intervals in a second direction, and the second direction intersects the first direction. In some embodiments, the isolation groove 300 may include a plurality of first isolation grooves arranged at intervals. The first isolation grooves extend in the first direction and are disposed between two adjacent columns of the capacitor contact structures 100.

In some embodiments, the isolation groove 300 may further include a plurality of second isolation grooves arranged at intervals. The second isolation grooves extend in the second direction, are disposed between two adjacent rows of the capacitor contact structures 100, and penetrate through a plurality of the first isolation grooves.

In some embodiments, the semiconductor structure may further include a plurality of capacitor structures 400. The capacitor structures 400 are disposed on the substrate, and are in contact with the capacitor contact structures 100 in a one-to-one correspondence.

In some embodiments, the semiconductor structure may further include a support structure.

Still referring to FIG. 22, the support structure may include a first support layer 411, a second support layer 412, and a third support layer 413 (not shown in FIG. 22) that are sequentially stacked from bottom to top. The support structure includes a plurality of capacitor holes 430 penetrating the first support layer 411, the second support layer 412, and the third support layer 413, where the capacitor holes 430 are arranged in a one-to-one correspondence with the capacitor contact structures 100, and the capacitor holes 430 expose the capacitor contact structures 100.

In such case, the isolation groove 300 further penetrates the first support layer 411 in the thickness direction.

In some embodiments, still referring to FIG. 22, the capacitor structure 400 may include a lower electrode 440, a capacitor dielectric layer 450, and an upper electrode 460.

The lower electrode 440 is disposed on a sidewall and a bottom of the capacitor hole 430, is connected to each of the first support layer 411, the second support layer 412, and the third support layer 413, and is in contact with the capacitor contact structure 100. The capacitor dielectric layer 450 is disposed on a surface of the lower electrode 440 and in the isolation groove 300. The upper electrode 460 is disposed on a surface of the capacitor dielectric layer 450.

In some embodiments, still referring to FIG. 22, a gap is provided between upper electrodes 460.

In some embodiments, still referring to FIG. 22, the capacitor structure 400 may further include a filling conductive layer 470. The filling conductive layer 470 may fill the gap between the upper electrodes 460.

In some examples, the filling conductive layer 470 is electrically connected to the upper electrode 460, so as to be connected to a metal interconnection wire on the capacitor structure 400.

It should be noted that, the method for fabricating a semiconductor structure in some embodiments of the present invention may be used to fabricate a corresponding semiconductor structure. Therefore, the technical features of the method embodiments and the structure embodiments may be interchanged and supplemented with each other provided that there is no conflict, so that a person skilled in the art can learn the technical content of the embodiments of the present invention.

The technical features of some embodiments described above may be combined arbitrarily. For brevity of description, not all possible combinations of the technical features of the embodiments are described. However, the combinations of these technical features should be considered as falling within the scope of this specification provided that there is no contradiction between the combinations.

The above-mentioned embodiments merely describe some implementations of the embodiments of the present invention, and description of these implementations is relatively specific and detailed, but should not be understood as a limitation on the scope of this invention. It should be noted that a person of ordinary skill in the art can make any variations and improvements without departing from the concept of the embodiments of the present invention, and these variations and improvements shall fall within the protection scope of the embodiments of the present invention. Therefore, the protection scope of the embodiments of the present invention shall be subject to the appended claims.

What is claimed is:

1. A semiconductor structure, comprising:
a substrate, wherein a plurality of capacitor contact structures arranged at intervals are formed on the substrate;
an isolation structure, wherein the isolation structure is disposed on the substrate and between adjacent capacitor contact structures, and a top surface of the isolation structure is not higher than a top surface of each capacitor contact structure; and
an isolation groove, wherein the isolation groove extends from the top surface of the isolation structure to an interior of the isolation structure, and a spacing is provided between the isolation groove and the capacitor contact structure.

2. The semiconductor structure according to claim 1, wherein the plurality of capacitor contact structures are arrayed in a plurality of rows and a plurality of columns, the plurality of the capacitor contact structures of a same column are arranged at intervals in a first direction, the plurality of the capacitor contact structures of a same row are arranged at intervals in a second direction, and the second direction intersects the first direction; and
the isolation groove comprises a plurality of first isolation grooves arranged at intervals, and the first isolation grooves extend in the first direction and are disposed between two adjacent columns of the capacitor contact structures.

3. The semiconductor structure according to claim 2, wherein the isolation groove comprises a plurality of second isolation grooves arranged at intervals, the second isolation grooves extend in the second direction, are disposed between two adjacent rows of the capacitor contact structures, and penetrate through a plurality of the first isolation grooves.

4. The semiconductor structure according to claim 1, further comprising a plurality of capacitor structures, wherein the capacitor structures are disposed on the substrate, and are in contact with the capacitor contact structures in a one-to-one correspondence.

5. The semiconductor structure according to claim 4, further comprising a support structure, wherein the support structure comprises a first support layer, a second support layer, and a third support layer that are sequentially stacked from bottom to top, and the support structure comprises a plurality of capacitor holes penetrating the first support layer, the second support layer, and the third support layer, wherein the capacitor holes are arranged in a one-to-one correspondence with the capacitor contact structures, and the capacitor holes expose the capacitor contact structures;
wherein the isolation groove penetrates the first support layer in a thickness direction; and
wherein the capacitor structure comprises:
a lower electrode, wherein the lower electrode is disposed on a sidewall and a bottom of the capacitor hole, is connected to each of the first support layer, the second support layer, and the third support layer, and is in contact with the capacitor contact structure;
a capacitor dielectric layer, wherein the capacitor dielectric layer is disposed on a surface of the lower electrode and in the isolation groove; and
an upper electrode, wherein the upper electrode is disposed on a surface of the capacitor dielectric layer.

6. The semiconductor structure according to claim 5, wherein a gap is provided between the upper electrodes, and the capacitor structure further comprises:
a filling conductive layer for filling the gap.

7. A method for fabricating a semiconductor structure, comprising:
providing a substrate;
forming a plurality of capacitor contact structures arranged at intervals on the substrate;
filling a gap between adjacent capacitor contact structures with an isolation structure, wherein a top surface of the isolation structure is not higher than a top surface of each capacitor contact structure; and
forming an isolation groove, wherein the isolation groove extends from the top surface of the isolation structure to an interior of the isolation structure, and a spacing is provided between the isolation groove and the capacitor contact structure.

8. The method for fabricating a semiconductor structure according to claim 7, wherein the plurality of capacitor contact structures are arrayed in a plurality of rows and a plurality of columns, the plurality of the capacitor contact structures of a same column are arranged at intervals in a first direction, the plurality of the capacitor contact structures of a same row are arranged at intervals in a second direction, and the second direction intersects the first direction; and
wherein the forming an isolation groove comprises:
forming a first patterned mask layer on the capacitor contact structure and the isolation structure, wherein the first patterned mask layer comprises a plurality of parallel first mask patterns arranged at intervals, the first mask patterns extend in a first direction, and an orthographic projection of a gap between adjacent first mask patterns on an upper surface of the substrate is located between two adjacent columns of the capacitor contact structures; and
etching the isolation structure based on the first patterned mask layer to form a plurality of first isolation grooves arranged at intervals, wherein the first isolation grooves extend in the first direction and are disposed between two adjacent columns of the capacitor contact structures.

9. The method for fabricating a semiconductor structure according to claim 8, wherein the forming a first patterned mask layer on the substrate comprises:
forming a first mask layer on the capacitor contact structure and the isolation structure;
forming, on an upper surface of the first mask layer, a plurality of parallel first submask patterns that are arranged at intervals and extend in the first direction;
forming a first sacrificial pattern on a sidewall of the first submask pattern, and removing the first submask pattern to retain a plurality of parallel first sacrificial patterns that are arranged at intervals and extend in the first direction;
forming a first filling mask layer, wherein the first filling mask layer fills a gap between adjacent first sacrificial patterns, and an upper surface of the first filling mask layer is not higher than an upper surface of the first sacrificial pattern;
removing the first sacrificial pattern to form a first initial trench between adjacent first filling mask layers; and
etching the first mask layer along the first initial trench to obtain the first patterned mask layer.

10. The method for fabricating a semiconductor structure according to claim 9, wherein the forming a first sacrificial pattern on a sidewall of the first submask pattern comprises:
forming a first sacrificial material layer on an upper surface of the first mask layer exposed between adjacent first submask patterns, the sidewall of the first submask pattern, and a top of the first submask pattern; and
removing the first sacrificial material layer disposed on the upper surface of the first mask layer exposed between adjacent first submask patterns and on the top of the first submask pattern, and retaining the first sacrificial material layer disposed on the sidewall of the first submask pattern as the first sacrificial pattern.

11. The method for fabricating a semiconductor structure according to claim 9, wherein the forming a first filling mask layer comprises:
forming a first filling material layer on the first mask layer, wherein the first filling material layer fills a gap between adjacent first sacrificial patterns and covers the first sacrificial pattern; and
etching the first filling material layer to remove the first filling material layer on a top of the first sacrificial pattern, and retaining the first filling material layer disposed between adjacent first sacrificial patterns as the first filling mask layer.

12. The method for fabricating a semiconductor structure according to claim 8, wherein the forming an isolation groove further comprises:
forming a second patterned mask layer on the capacitor contact structure and the isolation structure, wherein the second patterned mask layer comprises a plurality of parallel second mask patterns arranged at intervals, the second mask patterns extend in a second direction, the second direction intersects the first direction, and an orthographic projection of a gap between adjacent second mask patterns on an upper surface of the substrate is located between two adjacent rows of the capacitor contact structures; and
etching the isolation structure based on the second patterned mask layer to form a plurality of second isolation grooves arranged at intervals, wherein the second isolation grooves extend in the second direction, are disposed between two adjacent rows of the capacitor contact structures, and penetrate through a plurality of the first isolation grooves.

13. The method for fabricating a semiconductor structure according to claim 12, wherein before the forming a first patterned mask layer and a second patterned mask layer on the capacitor contact structure and the isolation structure, the forming an isolation groove further comprises: forming a pattern transfer material layer;
before etching the isolation structure, transferring the first mask pattern and the second mask pattern to the pattern transfer material layer to form a pattern transfer layer; and
etching the isolation structure based on the first patterned mask layer, the second patterned mask layer, and the pattern transfer layer to form the plurality of first isolation grooves and the plurality of second isolation grooves arranged at intervals.

14. The method for fabricating a semiconductor structure according to claim 7, after the forming an isolation groove, further comprising:
forming a plurality of capacitor structures on the substrate, wherein the capacitor structures are in contact with the capacitor contact structures in a one-to-one correspondence.

15. The method for fabricating a semiconductor structure according to claim 14, wherein the forming a plurality of capacitor structures on the substrate comprises:
forming a first support layer on an upper surface of the isolation structure, wherein the first support layer covers a top surface of the capacitor contact structure, and the isolation groove penetrates the first support layer in a thickness direction;
after forming the isolation groove, forming a first capacitor sacrificial layer on the first support layer, wherein the first capacitor sacrificial layer fills the isolation groove;
forming a second support layer on an upper surface of the first capacitor sacrificial layer;
forming a second capacitor sacrificial layer on an upper surface of the second support layer;
forming a third support layer on an upper surface of the second capacitor sacrificial layer;
forming a plurality of capacitor holes, wherein the capacitor hole penetrates the third support layer, the second capacitor sacrificial layer, the second support layer, the first capacitor sacrificial layer, and the first support layer to expose the capacitor contact structure;
forming a lower electrode on a sidewall and a bottom of the capacitor hole;
removing the first capacitor sacrificial layer and the second capacitor sacrificial layer;
forming a capacitor dielectric layer on a surface of the lower electrode and in the isolation groove; and
forming an upper electrode on a surface of the capacitor dielectric layer.

16. The method for fabricating a semiconductor structure according to claim 15, wherein a gap is provided between the upper electrodes, and after the forming an upper electrode, the method further comprises:
forming a filling conductive layer, wherein the filling conductive layer fills at least the gap.

17. The method for fabricating a semiconductor structure according to claim 7, further comprising:
forming a sidewall dielectric layer on a sidewall of the capacitor contact structure.

18. The method for fabricating a semiconductor structure according to claim 9, after the forming an isolation groove, further comprising:
removing the first patterned mask layer and the first filling mask layer.

19. The method for fabricating a semiconductor structure according to claim 15, wherein the removing the first capacitor sacrificial layer and the second capacitor sacrificial layer comprises:
forming a mask stack, wherein the mask stack covers a top surface of the lower electrode and seals the capacitor hole;
forming a photoresist layer on an upper surface of the mask stack;
patterning the photoresist layer to form a photoresist pattern on the photoresist layer, wherein the photoresist pattern exposes a portion of the upper surface of the mask stack;
etching the mask stack based on the photoresist layer to form a plurality of openings in the mask stack, wherein the openings expose a portion of the third support layer;
removing the top surface of the lower electrode;
transferring a pattern of the openings to the third support layer to form a capacitor opening hole, wherein the capacitor opening hole exposes a portion of the second capacitor sacrificial layer;
removing the second capacitor sacrificial layer to expose the second support layer;
transferring a pattern of the capacitor opening hole to the second support layer to expose a portion of the first capacitor sacrificial layer; and
removing the first capacitor sacrificial layer to expose the first support layer.

20. A dynamic random access memory comprising a semiconductor structure, wherein the semiconductor structure comprises:
a substrate, wherein a plurality of capacitor contact structures arranged at intervals are formed on the substrate;
an isolation structure, wherein the isolation structure is disposed on the substrate and between adjacent capacitor contact structures, and a top surface of the isolation structure is not higher than a top surface of each capacitor contact structure; and
an isolation groove, wherein the isolation groove extends from the top surface of the isolation structure to an interior of the isolation structure, and a spacing is provided between the isolation groove and the capacitor contact structure.
